(19) United States
(12) Patent Application Publication
(10) Pub. No.: US 2015/0055419 A1
(43) Pub. Date: Feb. 26, 2015

(54) CONTROLLER, MEMORY SYSTEM, AND METHOD

(71) Applicant: Kabushiki Kaisha Toshiba, Minato-ku (JP)

(72) Inventors: Kiyotaka IWASAKI, Kawasaki-shi (JP); Takashi Ide, Yokohama-shi (JP); Kouji Watanabe, Adachi-ku (JP)

(73) Assignee: Kabushiki Kaisha Toshiba, Minato-ku (JP)

(21) Appl. No.: 14/143,478

(22) Filed: Dec. 30, 2013

Related U.S. Application Data
(60) Provisional application No. 61/869,423, filed on Aug. 23, 2013.

(51) Int. Cl. G11C 16/32

(52) U.S. Cl. CPC G11C 16/32
USPC 365/185.33

(57) ABSTRACT

According to one embodiment, a memory system includes a memory chip and a controller. The controller is configured to count a first elapsed time from a start of an Erase process when causing the memory chip to execute the Erase process. The controller is configured to cause the memory chip to interrupt the Erase process after the first elapsed time exceeds a threshold value.

### CROSS-REFERENCE TO RELATED APPLICATIONS

This application is based upon and claims the benefit of priority from U.S. Provisional Patent Application No. 61/869,423, filed on Aug. 23, 2013; the entire contents of which are incorporated herein by reference.

### FIELD

Embodiments described herein relate generally to a controller, a memory system, and a method.

### BACKGROUND

A memory system used in a computer system has mounted thereto a memory chip of flash memory in some cases. The memory system includes a controller. The controller causes the memory chip to execute various processes according to a command from a host.

### BRIEF DESCRIPTION OF THE DRAWINGS

FIG. 1 is a view illustrating an example of a configuration of a memory system according to an embodiment.

FIG. 2 is a flowchart for describing a schematic operation of a controller.

FIG. 3 is a sequence view for describing an example of a transmission and reception of information among components.

### DETAILED DESCRIPTION

In general, according to one embodiment, a memory system includes a memory chip and a controller. The controller is configured to count a first elapsed time from a start of an Erase process when causing the memory chip to execute the Erase process. The controller is configured to cause the memory chip to interrupt the Erase process after the first elapsed time exceeds a threshold value.

Exemplary embodiments of a memory system, a controller, and a method will be explained below in detail with reference to the accompanying drawings. The present invention is not limited to the following embodiments.

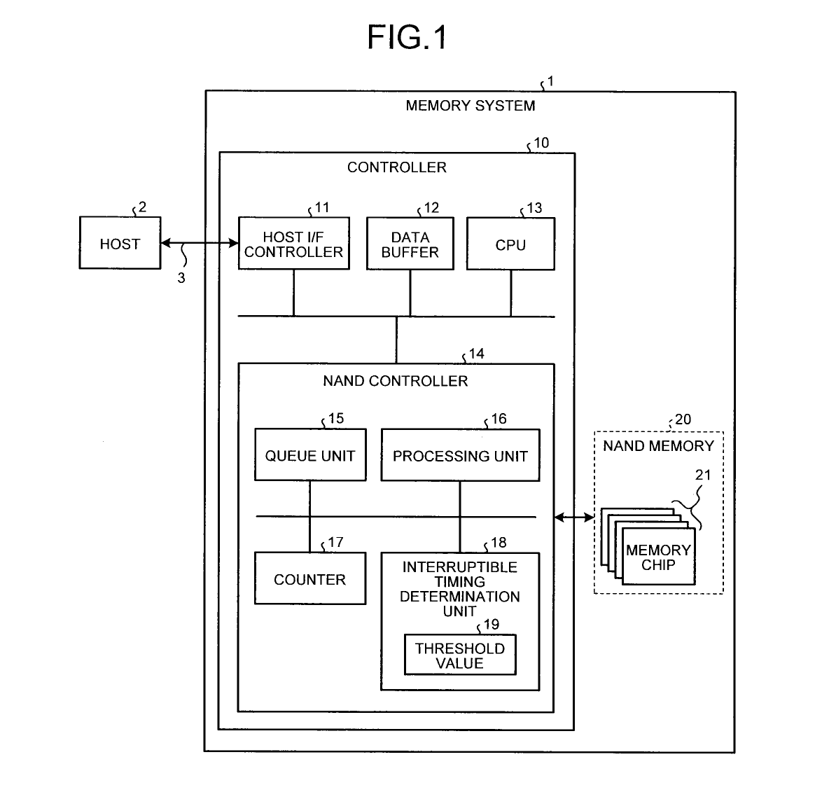

FIG. 1 is a view illustrating an example of a configuration of a memory system according to the embodiment. A memory system 1 is connected to a host 2 via a communication path 3. The host 2 is a computer, for example. The computer includes a personal computer, a portable computer, and a mobile communication device. The memory system 1 functions as an external storage device of the host 2. Any interface standard can be applied to the communication path 3. The host 2 can issue a Write command and a Read command to the memory system 1.

The memory system 1 has a controller 10 and NAND flash memory (NAND memory) 20 used as a storage. The type of the memory used as the storage is not limited to the NAND flash memory. For example, NOR flash memory, ReRAM (resistance random access memory), or MRAM (magnetoresistive random access memory) can be used.

The NAND memory 20 includes one or more memory chips 21, each having a memory cell array. The memory cell array includes multiple memory cells arranged in a matrix. Each memory cell array includes multiple blocks that are units of an Erase. Each block includes multiple pages that are units of Read and Write to the memory cell array.

The controller 10 receives a command from the host 2. The controller 10 executes control of the NAND memory 20 according to the received command.

The controller 10 includes a host interface (I/F) controller 11, a data buffer 12, a CPU 13, and a NAND controller 14. The host interface (I/F) 11, the data buffer 12, the CPU 13, and the NAND controller 14 are interconnected with a bus.

The data buffer 12 is composed of RAM, for example. The data buffer 12 is used as a buffer of transfer data between the host 2 and the NAND memory 20.

The host I/F controller 11 executes control of the communication path 3. The host I/F controller 11 also accepts a command from the host 2. The host I/F controller 11 executes the data transfer between the host 2 and the data buffer 12.

The CPU 13 executes control of the entire controller 10 by executing a firmware program. As one of the control, the CPU 13 generates a command to the NAND memory 20 according to the command accepted by the host I/F controller 11 from the host 2 or the internal process of the memory system 1. The CPU 13 registers the generated command to a queue unit 15 provided in the NAND controller 14. The internal process of the memory system 1 includes a wear leveling process or a garbage collection process.

The command generated by the CPU 13 may be the same as or different from the command received from the host 2. For example, the host 2 can issue a command of designating a location to be processed in a memory area formed by the NAND memory 20 by using a logical address. The CPU 13 translates the logical address included in the command from the host 2 into a physical address indicating a location in the memory cell array of each memory chip 21, as well as specifies the memory chip 21 to be processed. The CPU 13 then generates a command that designates the specified memory chip 21 as a destination, and that includes the physical address after the translation.

Unless otherwise specified, the command means the command generated by the CPU 13, or the command generated by a processing unit 16 provided in the NAND controller 14, in the following description.

The CPU 13 can generate a Read command, a Write command, an Erase command, and an Erase resume command. The later-described processing unit 16 can generate an Erase interrupt command. The Read command causes the memory chip 21 to execute a Read process of reading data from the memory cell array and outputting the same data. The Write command causes the memory chip 21 to execute a Write process of programming data in the memory cell array. The Erase command causes the memory chip 21 to execute the Erase process of Erasing a content stored in the block designated by the Erase command.

In the Erase process, a predetermined voltage is applied plural times to the memory cell array in a form of a pulse, in order to reduce a threshold potential of a memory cell transistor to a predetermined potential (erasure potential) or lower. The Erase process generally takes longer processing time than the Write process and the Read process. When a predetermined time has elapsed after the start of the Erase process, and the Write command or the Read command is registered to the queue unit 15, the controller 10 can interrupt the Erase process, and issue the registered command to the memory chip 21. The Erase interrupt command causes the memory chip 21 to execute the Erase interrupt process for interrupting the Erase process. The controller 10 can cause the memory chip 21 to resume the Erase process after the execution of the command is completed. The Erase resume command causes the memory chip 21 to resume the Erase process. When receiving the Erase resume command, the memory chip 21 can resume the Erase process from the state in which the Erase process progresses to some extent by the process before the Erase process is interrupted.

The controller 10 may be configured to interrupt the Erase process when any command is registered. The controller 10 may also be configured to interrupt the Erase process when a specific command is registered. For simplifying the description, it is supposed below that the controller 10 interrupts the Erase process when a predetermined time has elapsed after the start of the Erase process, and the Read command is registered.

The NAND controller 14 issues a command to the NAND memory 20, or executes the data transfer between the data buffer 12 and the NAND memory 20.

The NAND controller 14 includes the queue unit 15, the processing unit 16, a counter 17, and an interruptible timing determination unit 18. The queue unit 15, the processing unit 16, the counter 17, and the interruptible timing determination unit 18 are interconnected with a bus.

The queue unit 15 has therein a memory (command queue) having a queue structure to which a command is registered from the CPU 13. The queue unit 15 requests to extract the command registered therein on a timing according to an operation state (ready state or busy state) of the memory chip 21 that is the destination of the command, and to issue the extracted command to the processing unit 16.

Any structure is employed for recognizing the operation state of the memory chip 21 by the queue unit 15. For example, the queue unit 15 can recognize the operation state of the memory chip 21 based upon a ready/busy signal operated by the memory chip 21. It may be configured such that the processing unit 16 issues a status Read command to the memory chip, and the queue unit 15 recognizes the operation state according to status information replied from the memory chip.

The counter 17 counts an elapsed time after the start of the Erase process, and sequentially notifies the interruptible timing determination unit 18 of the count value. The elapsed time is counted for each memory chip 21.

The interruptible timing determination unit 18 stores therein a threshold value 19. The interruptible timing determination unit 18 compares the count value by the counter 17 and the threshold value 19, and when the count value exceeds the threshold value, it notifies the processing unit 16 of an interruptible notification. The threshold value 19 may preliminarily be set as a fixed value by a designer. The threshold value may be variable, and may be set from the outside (e.g., the host 2) of the controller 10 or the inside (e.g., the CPU 13) of the controller 10 on a predetermined timing (e.g., upon the start).

The processing unit 16 issues the command requested from the queue unit 15 to the NAND memory 20. After the interruptible notification involved with the memory chip 21 that currently executes the Erase process is received, and when a data access command whose destination is the memory chip 21 is registered to the queue unit 15, the processing unit 16 issues the Erase interrupt command whose destination is this memory chip 21.

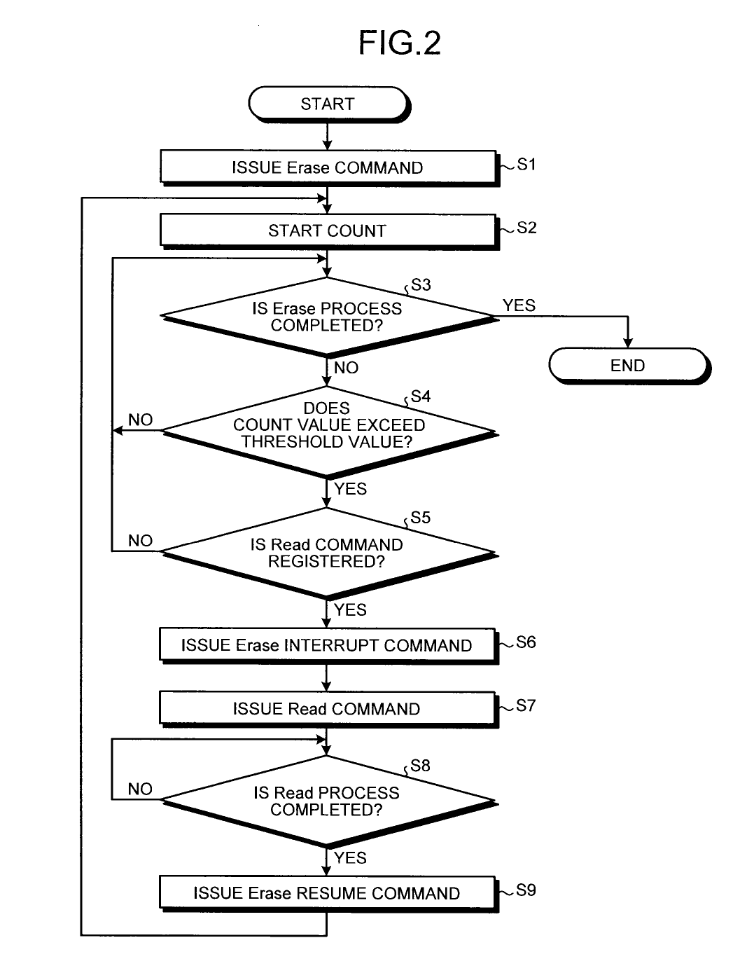

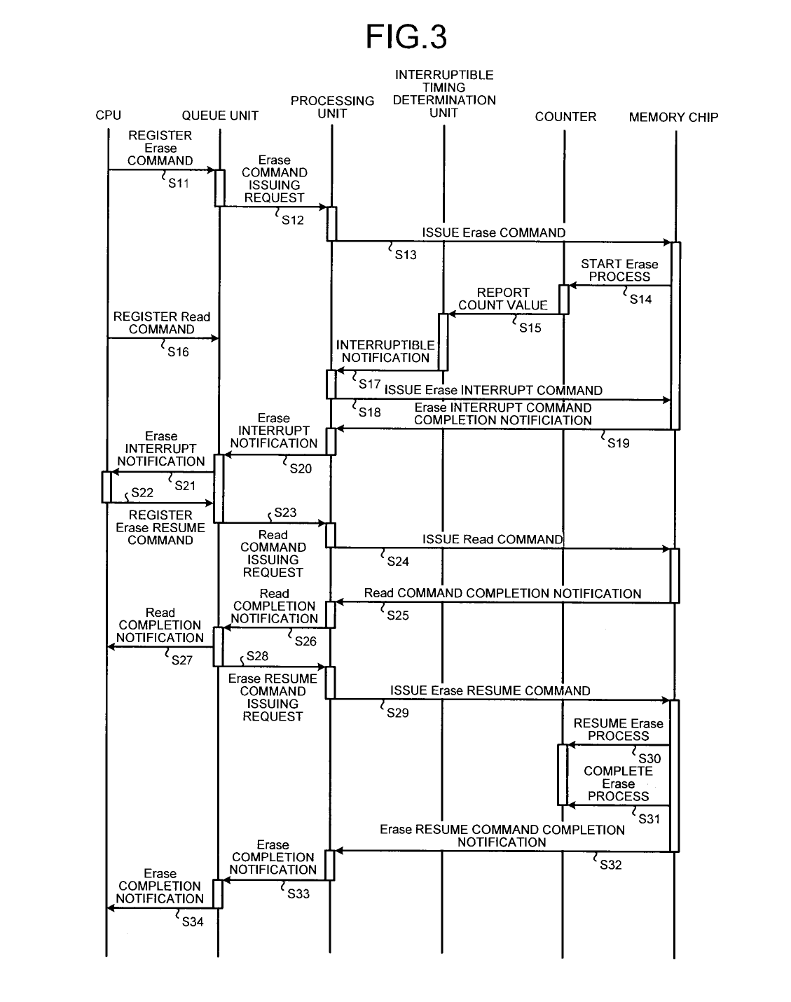

FIG. 2 is a flowchart for describing a schematic operation of the controller 10. The process in FIG. 2 (and in a later-described FIG. 3) is independently executed for each memory chip 21. FIG. 2 (and FIG. 3) are for describing an operation of any one (hereinafter referred to as a target memory chip 21) of the multiple memory chips 21.

When the processing unit 16 issues the Erase command to the target memory chip 21 (S1), the counter 17 starts the count (S2). The flow of the process is branched according to whether the Erase process is completed or not. When the target memory chip 21 completes the Erase process (S3, Yes), the controller 10 ends the operation upon the issuance of the Erase command.

When the target memory chip 21 does not complete the Erase process (S3, No), the interruptible timing determination unit 18 determines whether the count value exceeds the threshold value 19 or not (S4). The timing determination unit 18 executes the determination process in step S3 at all times after the start of the count. When the count value exceeds the threshold value 19 (S4, Yes), the processing unit 16 determines whether the Read command to the target memory chip 21 is registered to the queue unit 15 or not (S5). When the Read command to the target memory chip 21 is registered to the queue unit 15 (S5, Yes), the processing unit 16 issues the Erase interrupt command to the target memory chip 21 (S6).

When the count value does not exceed the threshold value 19 (S4, No), or the Read command to the target memory chip 21 is not registered to the queue unit 15 (S5, No), the controller 10 proceeds to the determination process in step S3.

After the process in step S6, the processing unit 16 issues the Read command to the target memory chip 21 (S7). Then, the controller 10 waits until the target memory chip 21 completes the Read process (S8, No). When the target memory chip 21 completes the Read process (S8, Yes), the processing unit 16 issues the Erase resume command to the target memory chip 21 (S9). After the Erase resume command is issued, the process in step S2 is again executed.

FIG. 3 is a sequence view for describing an example of a transmission and reception of information among components.

Firstly, the CPU 13 registers the Erase command to the queue unit 15 (S11). When the target memory chip 21 is in the ready state, for example, the queue unit 15 transmits an Erase command issuing request indicating the issuance of the Erase command to the processing unit 16 (S12). When receiving the Erase command issuing request, the processing unit 16 issues the Erase command to the target memory chip 21 (S13).

When receiving the Erase command, the target memory chip 21 starts the Erase process, and changes to the busy state. After recognizing the start of the Erase process (S14), the counter 17 starts counting, and sequentially reports the count value to the interruptible timing determination unit 18 (S15). The start of the Erase process can be recognized by the ready/busy signal or the status information. The time from the issuance of the Erase command to the start of the Erase process is significantly smaller than the time needed for the Erase process. Therefore, the counter 17 may start the count on the timing when the Erase command is issued.

The interruptible timing determination unit 18 compares the reported count value and the threshold value 19, and when the count value exceeds the threshold value 19, the interruptible timing determination unit 18 transmits the interruptible notification to the processing unit 16 (S17). In this case, the Read command is registered to the queue unit 15 from the CPU 13 on the timing between the process in step S15 and the process in step S16 (S16).

The processing unit 16 receives the interruptible notification. Since the Read command is registered to the queue unit 15, the processing unit 16 issues the Erase interrupt command to the target memory chip 21 (S18). When receiving the Erase interrupt command, the target memory chip 21 interrupts the Erase process that is executed so far, and transmits an Erase interrupt command completion notification indicating that the execution of the Erase interrupt command is completed to the processing unit 16 (S19).

When receiving the Erase interrupt command completion notification, the processing unit 16 transmits the Erase interrupt notification indicating that the Erase process is interrupted to the CPU 13 via the queue unit 15 (S20, S21). When receiving the Erase interrupt notification, the CPU 13 registers the Erase resume command to the queue unit 15 (S22).

The queue unit 15 has registered thereto the Read command and the Erase resume command just after the process in step S22. The queue unit 15 selects the Read command. For example, priority higher than the priority for the Erase resume command is set to the Read command, and the queue unit 15 selects the Read command based upon the set priority. The queue unit 15 transmits a Read command issuing request indicating the request for issuing the selected Read command to the processing unit 16 (S23). When receiving the Read command issuing request, the processing unit 16 issues the Read command to the target memory chip 21 (S24).

When receiving the Read command, the target memory chip 21 starts the Read process. After completing the Read process, the target memory chip 21 transmits a Read command completion notification indicating that the execution of the Read command is completed to the processing unit 16 (S25).

When receiving the Read command completion notification, the processing unit 16 transmits a Read completion notification indicating that the execution of the Read process is completed to the CPU 13 via the queue unit 15 (S26, S27).

Although not illustrated here, the Read process includes the transfer of the Read data. The Read data is transmitted to the processing unit 16 with the transmission of the notification in step S25, and is stored in the data buffer 12 by the processing unit 16. The CPU 13 can recognize that the Read data is stored in the data buffer 12 by receiving the Read completion notification.

Just after the process in step S27, the Erase process is interrupted, and the execution of one Read command is completed. The Erase resume command is registered in the queue unit 15. The queue unit 15 transmits an Erase resume command issuing request indicating the request of issuing the Erase resume command to the processing unit 16 (S28).

When another Read command is newly registered just before step S28, the queue unit 15 may transmit a Read command issuing request indicating the request of issuing another Read command. The queue unit 15 may also transmit the Erase resume command issuing request, when the number of the Read commands, which can be executed after the interruption of the Erase process, is set to a fixed value (e.g., “1”), and the number of the Read commands executed after the interruption of the Erase process reaches the set value.

When receiving the Erase resume command issuing request, the processing unit 16 transmits the Erase resume command to the target memory chip 21 (S29). When receiving the Erase resume command, the target memory chip 21 starts the Erase process, and changes to the busy state. When recognizing the resuming of the Erase process (S30), the counter 17 starts a new count. The count value is sequentially reported to the interruptible timing determination unit 18. The process of reporting the count value is not illustrated in the figure. When the counter 17 recognizes that the target memory chip 21 completes the Erase process (S31), it ends the count.

The target memory chip 21 transmits the Erase resume command completion notification indicating that the execution of the Erase resume command is completed to the processing unit 16 after the completion of the Erase process (S32). When receiving the Erase resume command completion notification, the processing unit 16 transmits the Erase completion notification indicating that the Erase process is completed to the CPU 13 via the queue unit 15 (S33, S34).

As described above, according to the embodiment, when the controller 10 causes the memory chip 21 to execute the Erase process, the controller 10 counts the elapsed time from the start of the execution of the Erase process, and when the count value exceeds the threshold value 19, the controller 10 can interrupt the Erase process. Thus, when the command is registered to the queue unit 15, the controller 10 can issue this command after the interruption of the Erase process. Specifically, when the Read process or the Write process is requested from the host 2 during the execution of the Erase process, the controller 10 can shorten the time taken till the completion of the execution of the requested Read process or the Write process.

The controller 10 causes the memory chip 21 to execute the Erase process for the time equal to or longer than the time set by the threshold value 19, and then, to interrupt the Erase process. Accordingly, the controller 10 can suppress the time till the completion of the execution of the Read process or the Write process within a certain time, while progressing the Erase process to some extent.

When the elapsed time from the start of the execution of the Erase process exceeds the threshold value 19, and when a command is registered to the queue unit 15, the controller 10 interrupts the Erase process, and issues the command registered to the queue unit 15 to the memory chip 21. With this process, the controller 10 can suppress the time till the completion of the execution of the Read process or the Write process within a certain time, while progressing the Erase process to some extent.

When the memory chip 21 completes the process involved with the command registered to the queue unit 15, the controller 10 causes the memory chip 21 to resume the Erase process. With this process, the controller 10 can resume the interrupted Erase process.

The controller 10 counts the elapsed time from the resuming of the Erase process, and after the count value exceeds the threshold value 19, the controller 10 interrupts the Erase process. Thus, when a command is registered to the queue unit 15 even after the Erase process is once interrupted and again started, the controller 10 can issue this command.

The threshold value 19 may be variable, and may be set from the inside or outside of the controller 10.

The threshold value 19 can be set to be equal to the processing time of the Write process of programming data to the memory chip 21. Thus, Read performance when the controller 10 issues the Read command during the execution of the Write process, and Read performance when the controller 10 issues the Read command during the execution of the Erase process can be set to be equal to each other. Specifically, variation in the Read performance can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory chip; and
a controller configured to count a first elapsed time from a start of an Erase process when causing the memory chip to execute the Erase process, and to cause the memory chip to interrupt the Erase process after the first elapsed time exceeds a threshold value.

2. The memory system according to claim 1, wherein
the controller includes a command queue to which a command is registered, and
when the first elapsed time exceeds the threshold value, and when a predetermined command is registered to the command queue, the controller interrupts the Erase process and issues the predetermined command to the memory chip.

3. The memory system according to claim 2, wherein
the controller resumes the Erase process when the memory chip completes a process according to the predetermined command.

4. The memory system according to claim 3, wherein
the controller counts a second elapsed time after the resuming of the Erase process, and when the second elapsed time exceeds the threshold value, the controller interrupts the Erase process.

5. The memory system according to claim 1, wherein
the threshold value is configured to be variable, and set from the inside or outside of the controller.

6. The memory system according to claim 1, wherein
the threshold value is equal to a processing time of a Write process of programming data to the memory chip.

7. The memory system according to claim 2, wherein
the predetermined command is a Read command or a Write command.

8. A controller that controls a memory chip,
the controller counting a first elapsed time from a start of an Erase process when causing the memory chip to execute the Erase process, and causing the memory chip to interrupt the Erase process after the first elapsed time exceeds a threshold value.

9. The controller according to claim 8 comprising
a command queue to which a command is registered, wherein
when the first elapsed time exceeds the threshold value, and when a predetermined command is registered to the command queue, the controller interrupts the Erase process and issues the predetermined command to the memory chip.

10. The controller according to claim 9,
resuming the Erase process when the memory chip completes a process according to the predetermined command.

11. The controller according to claim 10,
counting a second elapsed time after the resuming of the Erase process, and when the second elapsed time exceeds the threshold value, interrupting the Erase process.

12. The controller according to claim 8, wherein
the threshold value is configured to be variable, and set from the inside or outside of the controller.

13. The controller according to claim 8, wherein
the threshold value is equal to a processing time of a Write process of programming data to the memory chip.

14. The controller according to claim 9, wherein
the predetermined command is a Read command or a Write command.

15. A method of controlling a memory chip by a controller, the method comprising:
counting a first elapsed time from a start of an Erase process when causing the memory chip to execute the Erase process; and
interrupting the Erase process after the first elapsed time exceeds a threshold value.

16. The method according to claim 15, further comprising:
registering a command to a command queue; and
when the first elapsed time exceeds the threshold value, and when a predetermined command is registered to the command queue, interrupting the Erase process and issuing the predetermined command to the memory chip.

17. The method according to claim 16, further comprising:
resuming the Erase process when the memory chip completes a process according to the predetermined command.

18. The method according to claim 17, further comprising:
counting a second elapsed time after the resuming of the Erase process, and when the second elapsed time exceeds the threshold value, interrupting the Erase process.

19. The method according to claim 15, wherein
the threshold value is configured to be variable, and set from the inside or outside of the controller.

20. The method according to claim 15, wherein
the threshold value is equal to a processing time of a Write process of programming data to the memory chip.
